(19) United States
(12) Patent Application Publication
(10) Pub. No.: US 2014/0155622 A1
(43) Pub. Date: Jun. 5, 2014

(54) INDOLOCARBAZOLE DERIVATIVE AND ORGANIC ELECTROLUMINESCENCE DEVICE INCLUDING THE SAME

(71) Applicant: SAMSUNG DISPLAY CO., LTD., Yongin-City (KR)

(72) Inventor: Xiulan JIN, Yongin-City (KR)

(73) Assignee: SAMSUNG DISPLAY CO., LTD., Yongin-City (KR)

(21) Appl. No.: 14/089,981

(22) Filed: Nov. 26, 2013

(30) Foreign Application Priority Data
Nov. 30, 2012 (JP) 2012-263847

(51) Int. Cl. H01L 51/00

(52) U.S. Cl. CPC H01L 51/0072
USPC 548/418

(57) ABSTRACT

An indolocarbazole derivative and an organic electroluminescence device, the indolocarbazole derivative having a structure represented by A-L-B, wherein A and B are each independently an indolocarbazolyl group represented by one of Formulae (1) to (6), below:

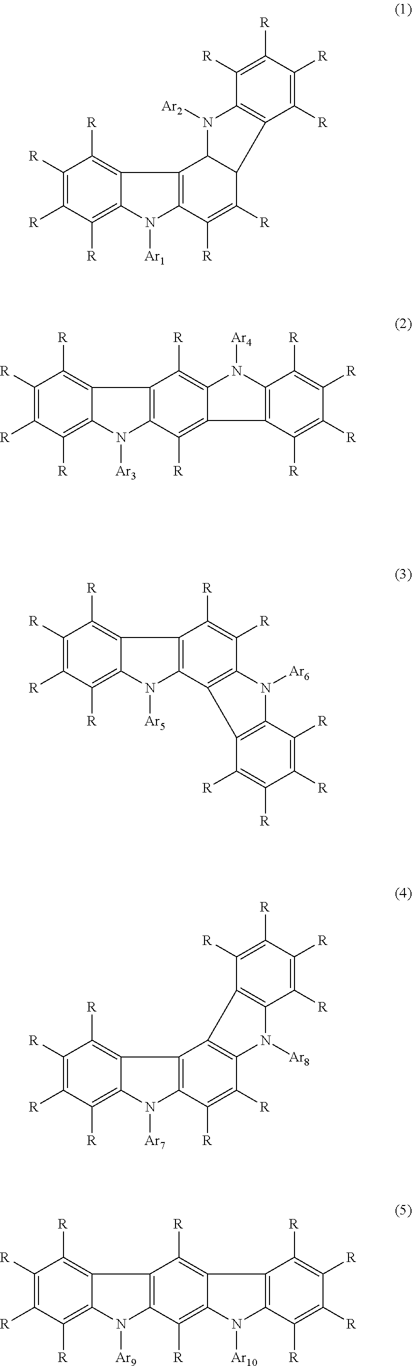

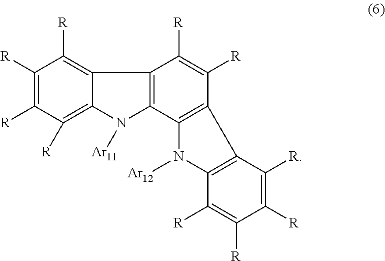

### CROSS-REFERENCE TO RELATED APPLICATION

Japanese Patent Application No. 2012-263847, filed on Nov. 30, 2012, in the Japanese Patent Office, and entitled: “INDOLOCARBAZOLE DERIVATIVE AND ORGANIC ELECTROLUMINESCENCE DEVICE INCLUDING THE SAME,” is incorporated by reference herein in its entirety.

### BACKGROUND

1. Field

Embodiments relate to an indolocarbazole derivative and an organic electroluminescence device including the same.

2. Description of the Related Art

In recent years, organic electroluminescence (EL) displays are one type of image displays that have been actively developed. Unlike a liquid crystal display (or the like), the organic EL display is so-called a self-luminescent display that recombines holes and electrons injected from an anode and a cathode in a light-emitting layer to thus emit light from a light-emitting material including an organic compound, thereby displaying an image.

An example of a light-emitting device (hereinafter referred to as an organic EL device) may include an organic EL device that includes a positive electrode, a hole transport layer disposed on the positive electrode, a light-emitting layer disposed on the hole transport layer, an electron transport layer disposed on the light-emitting layer, and a negative electrode disposed on the electron transport layer. Holes injected from the positive electrode may be injected into the light-emitting layer via the hole transport layer. Electrons may be injected from the negative electrode, and then injected into the light-emitting layer via the electron transport layer. The holes and the electrons injected into the light-emitting layer may be recombined to generate excitons within the light-emitting layer. The organic EL device may emit light generated by radiation and deactivation of the excitons.

### SUMMARY

Embodiments are directed to an indolocarbazole derivative and an organic electroluminescence device including the same.

The embodiments may be realized by providing an indolocarbazole derivative having a structure represented by A-L-B, wherein A and B are each independently an indolocarbazolyl group represented by one of Formulae (1) to (6), below:

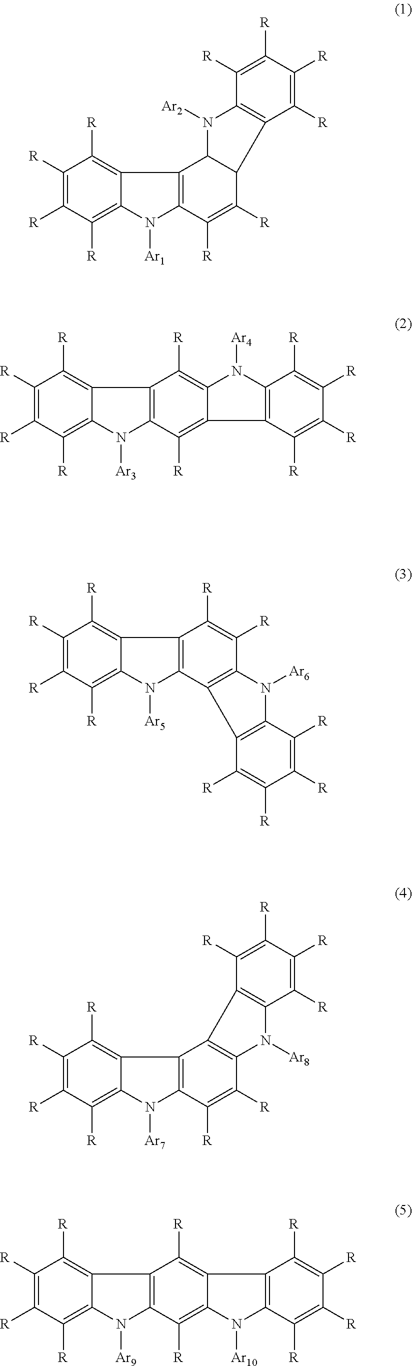

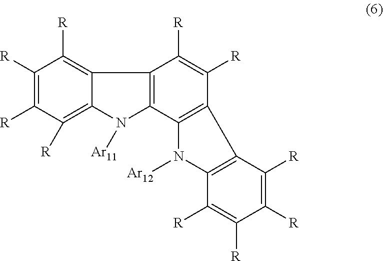

wherein, L is a connecting part and is selected from a single bond, an arylene group, or a heteroarylene group, Ar₁ to Ar₁₂ are each independnetly a substituted or unsubstituted aryl or heteroaryl group, and each R is independently hydrogen, an alkyl group, an aryl group, a heteroaryl group having less than or equal to 20 carbon atoms, or the connecting part L.

The indolocarbazole group A may be represented by one of Formulae (1) to (6) and the indolocarbazole group B may be represented by a different one of Formulae (1) to (6), and the indolocarbazole derivative may have an asymmetric structure.

When the indolocarbazolyl group A and the indolocarbazolyl group B are each independently represented by one of Formulae (1) to (6) a kind of Ar₁ to Ar₁₂ of the indolocarbazole group A may be different from a kind of Ar₁ to Ar₁₂ of the indolocarbazole group B, a number and/or a kind of R of the indolocarbazole group A may be different from a number and/or a kind of R of the indolocarbazole group B, or a binding site of the connecting part L to the indolocarbazole group A may be different from a binding site of the connecting part L to the indolocarbazole group B.

The connecting part L may be the single bond.

At least one end of the single bond may be bound to a benzene ring included in an indolocarbazole skeleton of the indolocarbazolyl group A or the indolocarbazolyl group B.

Both ends of the single bond may be bound to benzene rings respectively included in the indolocarbazole skeletons of the indolocarbazolyl group A and the indolocarbazolyl group B.

The connecting part L may be the single bond.

The embodiments may also be realized by providing an organic electroluminescence device including an emission layer, the emission layer including an indolocarbazole derivative having a structure represented by A-L-B, wherein A and B are each independently an indolocarbazolyl group represented by one of Formulae (1) to (6), below:

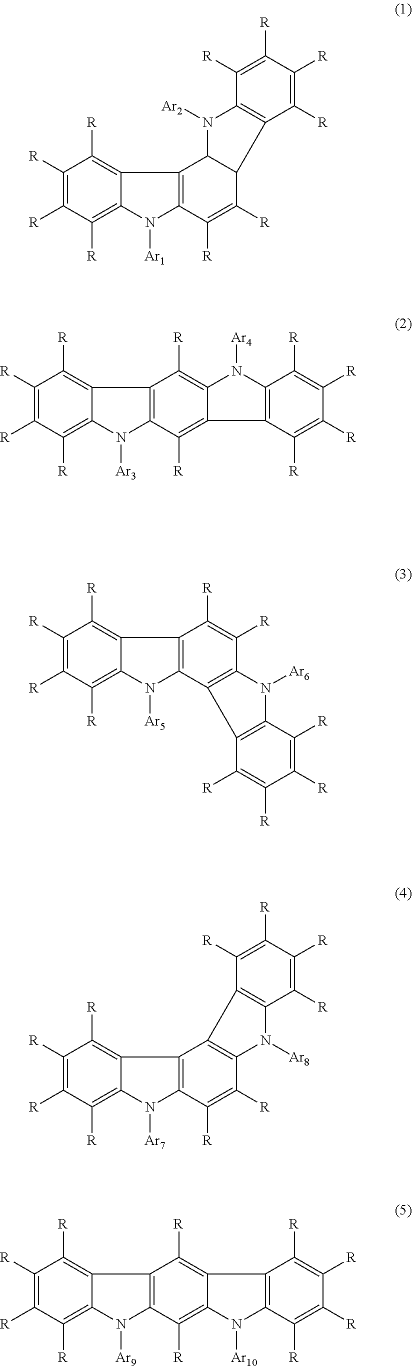

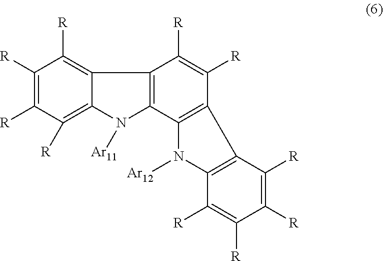

wherein, L is a connecting part and is selected from a single bond, an arylene group, or a heteroarylene group, Ar₁ to Ar₁₂ are each independnetly a substituted or unsubstituted aryl or heteroaryl group, and each R is independently hydrogen, an alkyl group, an aryl group, a heteroaryl group having less than or equal to 20 carbon atoms, or the connecting part L.

The indolocarbazole group A may be represented by one of Formulae (1) to (6) and the indolocarbazole group B may be represented by a different one of Formulae (1) to (6), and the indolocarbazole derivative may have an asymmetric structure.

When the indolocarbazolyl group A and the indolocarbazolyl group B are each independently represented by one of Formulae (1) to (6) a kind of Ar₁ to Ar₁₂ of the indolocarbazole group A may be different from a kind of Ar₁ to Ar₁₂ of the indolocarbazole group B, a number and/or a kind of R of the indolocarbazole group A may be different from a number and/or a kind of R of the indolocarbazole group B, or a binding site of the connecting part L to the indolocarbazole group A may be different from a binding site of the connecting part L to the indolocarbazole group B.

The connecting part L may be the single bond.

At least one end of the single bond may be bound to a benzene ring included in an indolocarbazole skeleton of the indolocarbazolyl group A or the indolocarbazolyl group B.

Both ends of the single bond may be bound to benzene rings respectively included in the indolocarbazole skeletons of the indolocarbazolyl group A and the indolocarbazolyl group B.

The connecting part L may be the single bond.

### BRIEF DESCRIPTION OF THE DRAWING

Features will be apparent to those of skill in the art by describing in detail exemplary embodiments with reference to the attached drawing in which:

FIG. 1 illustrates a schematic diagram of an organic EL device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figure, the dimensions of layers and regions may be exaggerated for clarity of illustration. Like reference numerals refer to like elements throughout.

According to an embodiment, an organic EL device having high efficiency and long life may be realized by using an asymmetric indolocarbazole compound, e.g., an asymmetric indolocarbazole dimer, as a host material of an emission layer.

The indolocarbazole derivative according to an embodiment may be represented by a general formula of A-L-B. For example, A and B may each independently be an indolocarbazole group represented by one of the following Formulae (1) to (6).

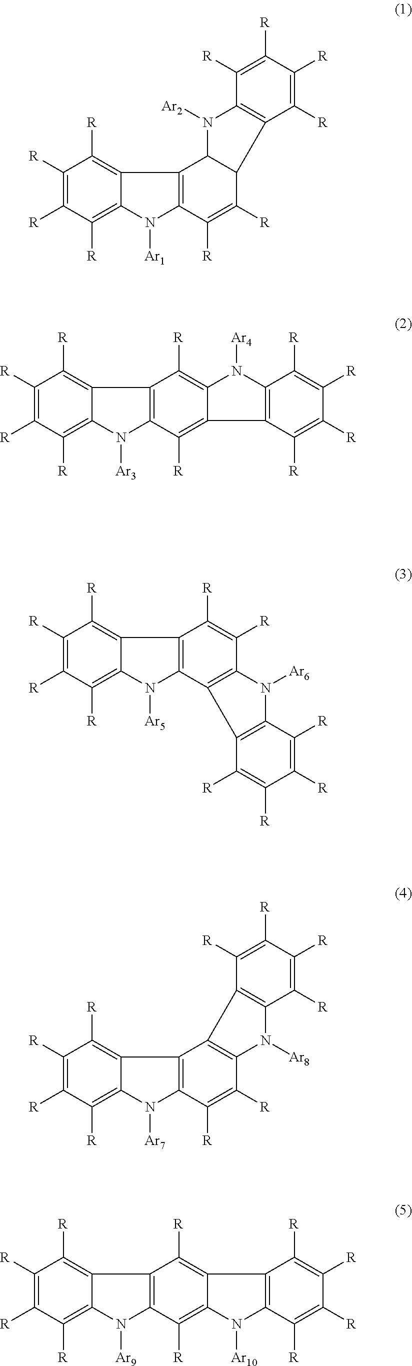

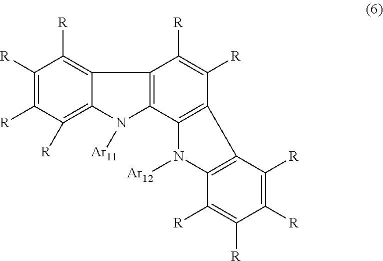

In the general formula of A-L-B, L may be a connecting part or linking group, and may be selected from a single bond, an arylene group, or a heteroarylene group. In Formulae (1) to (6), Ar₁ to Ar₁₂ may each independently be a substituted or unsubstituted aryl or heteroaryl group, and R may be hydrogen, an alkyl group, an aryl group, or a heteroaryl group having less than or equal to 20 carbon atoms, or the connecting part L.

The indolocarbazole derivative according to an embodiment may be an indolocarbazole dimer having an asymmetric structure. For example, the indolocarbazole derivative may include an indolocarbazolyl group positioned at A and another indolocarbazolyl group positioned at B with the connecting part L therebetween. An indolocarbazole skeleton may have the structure of one of Formulae (1) to (6), above. For example, the compound according to an embodiment may be obtained by selecting two different structures from among the six kinds of the indolocarbazole groups or skeletons represented by Formulae (1) to (6).

In an implementation, two indolocarbazolyl groups having the same general or base structure may be selected from the indolocarbazole skeletons represented by Formulae (1) to (6) as A and B. In this case, the kinds of Ar₁ to Ar₁₂ may be different, the number and/or the kind of R may be different, and/or the sites bound with the connecting part L, e.g., the R group location, may be different. Thus, an indolocarbazole dimer having an asymmetric structure with the connecting part L therebetween may be obtained. When the indolocarbazole skeletons of A and B are the same, each of Ar₁ to Ar₁₂ of each indolocarbazolyl group may be different, or the number or the kind of the R substituent may be different, thereby obtaining the asymmetric structure with the connecting part L therebetween. In addition, the asymmetric structure with respect to the connecting part L may be obtained by selecting different connecting or bonding sites of the connecting part L in each of the indolocarbazolyl groups. In addition, by combining the above-described conditions, the asymmetric structure of the indolocarbazole derivative with the connecting part L therebetween may be obtained.

In the indolocarbazole derivative according to an embodiment, when the connecting part L is a single bond, a distance between two indolocarbazolyl groups may be decreased, and an angle between two faces formed by the two indolocarbazolyl groups may be increased. In the indolocarbazole derivative according to an embodiment, at least one end of the single bond may be combined with or bound to a benzene ring included in the indolocarbazole skeleton of one of the indolocarbazole groups (A or B). In an implementation, both ends of the single bond may be bound to benzene rings included in the indolocarbazole skeletons of each of the indolocarbazole groups (A and B). Accordingly, the planarity of the indolocarbazole derivative may be lowered, and stacking effect between indolocarbazole derivatives may be restrained. In an implementation, by selecting the connecting part L as the single bond, e.g., by connecting the indolocarbazole groups directly, the amorphous properties of the indolocarbazole derivative may be improved. When this indolocarbazole derivative is used as the host material of an emission layer, the layer stability of the emission layer may be improved as described above.

The indolocarbazole derivative according to an embodiment may include materials represented by one of the following Formulae 19-24.

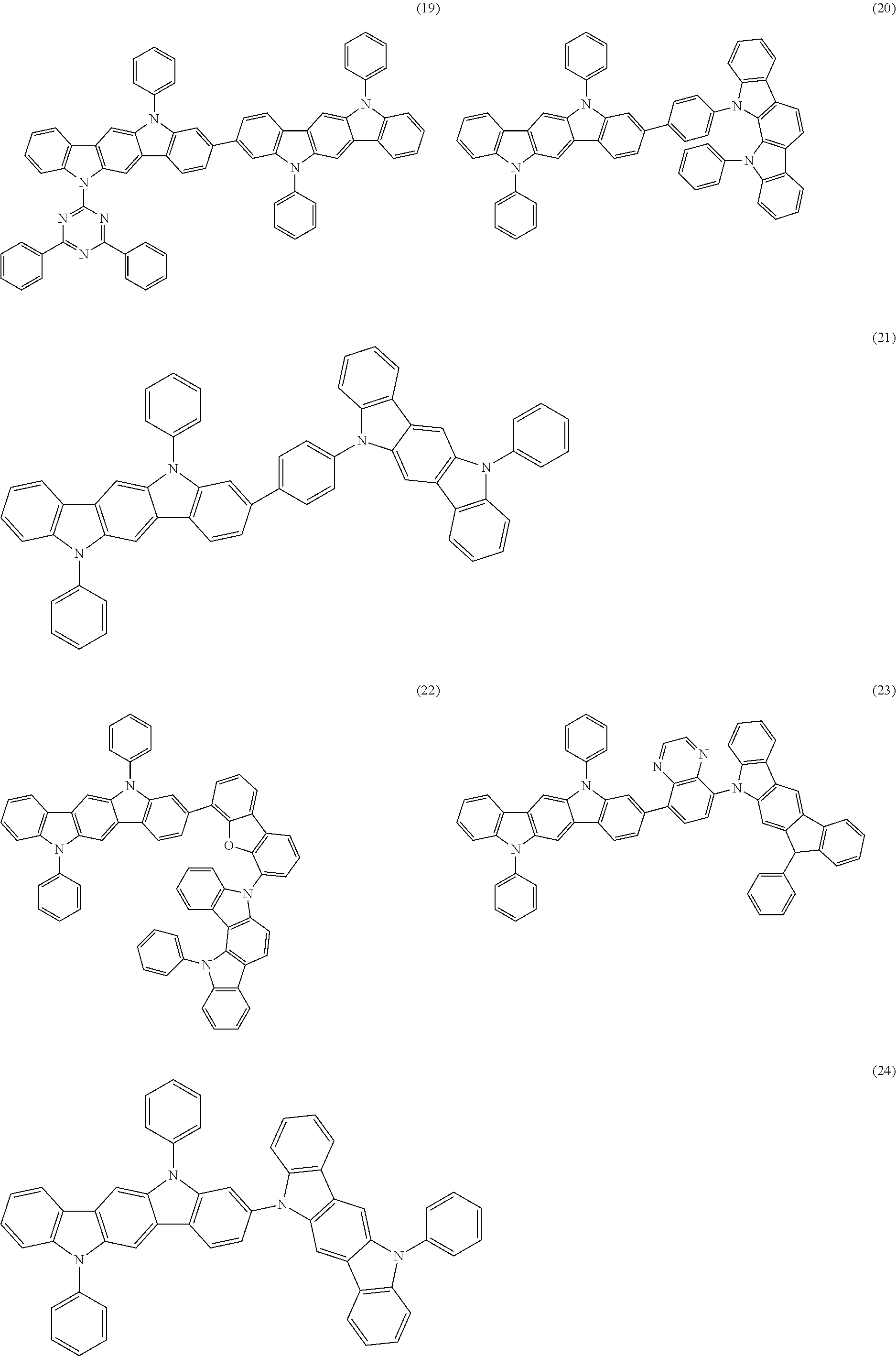

In an implementation, the indolocarbazole derivative according to an embodiment may include materials represented by one of the following Formulae 25-30.

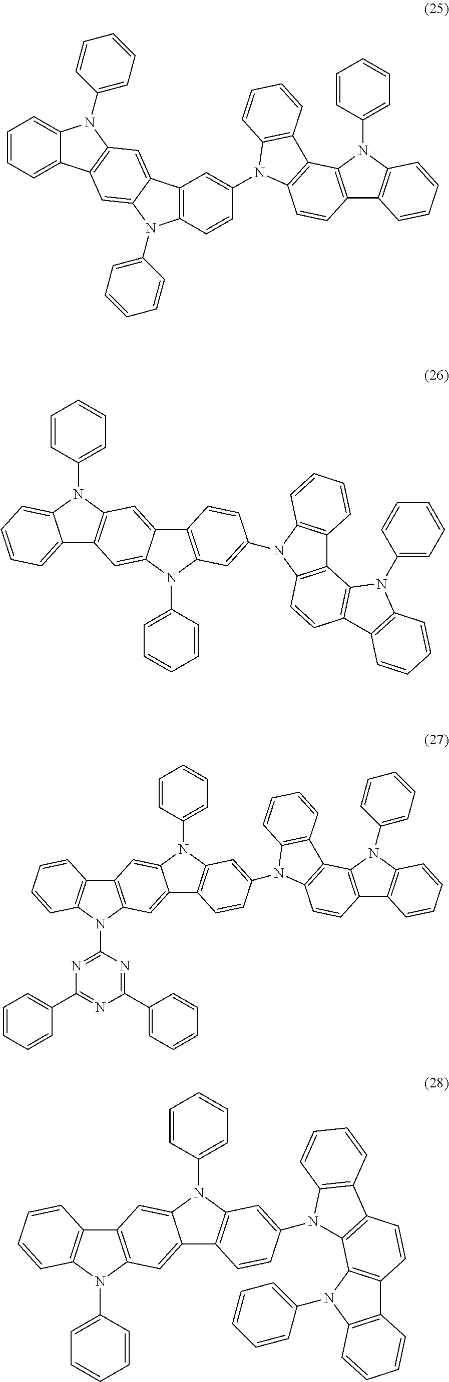 [SMILES: c1ccc(-n2c3ccccc3c3cc4c(cc32)c2cc(-n3c5ccccc5c5c3ccc3c6ccccc6n(-c6ccccc6)c35)ccc2n4-c2ccccc2)cc1 ; c1ccc(-n2c3ccccc3c3cc4c(cc32)c2ccc(-n3c5ccccc5c5c3ccc3c6ccccc6n(-c6ccccc6)c35)cc2n4-c2ccccc2)cc1 ; c1ccc(-c2nc(-c3ccccc3)nc(-n3c4ccccc4c4cc5c(cc43)c3ccc(-n4c6ccccc6c6c4ccc4c7ccccc7n(-c7ccccc7)c46)cc3n5-c3ccccc3)n2)cc1 ; c1ccc(-n2c3ccccc3c3cc4c(cc32)c2ccc(-n3c5ccccc5c5ccc6c7ccccc7n(-c7ccccc7)c6c53)cc2n4-c2ccccc2)cc1]

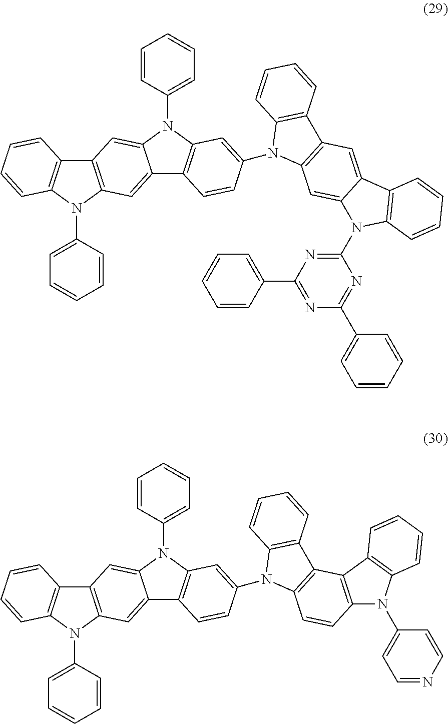 [SMILES: c1ccc(-c2nc(-c3ccccc3)nc(-n3c4ccccc4c4cc5c6ccccc6n(-c6ccc7c8cc9c(cc8n(-c8ccccc8)c7c6)c6ccccc6n9-c6ccccc6)c5cc43)n2)cc1 ; c1ccc(-n2c3ccccc3c3cc4c(cc32)c2ccc(-n3c5ccccc5c5c6c7ccccc7n(-c7ccncc7)c6ccc53)cc2n4-c2ccccc2)cc1]

In an implementation, the indolocarbazole derivative according to an embodiment may include materials represented by one of the following Formulae 31-40.

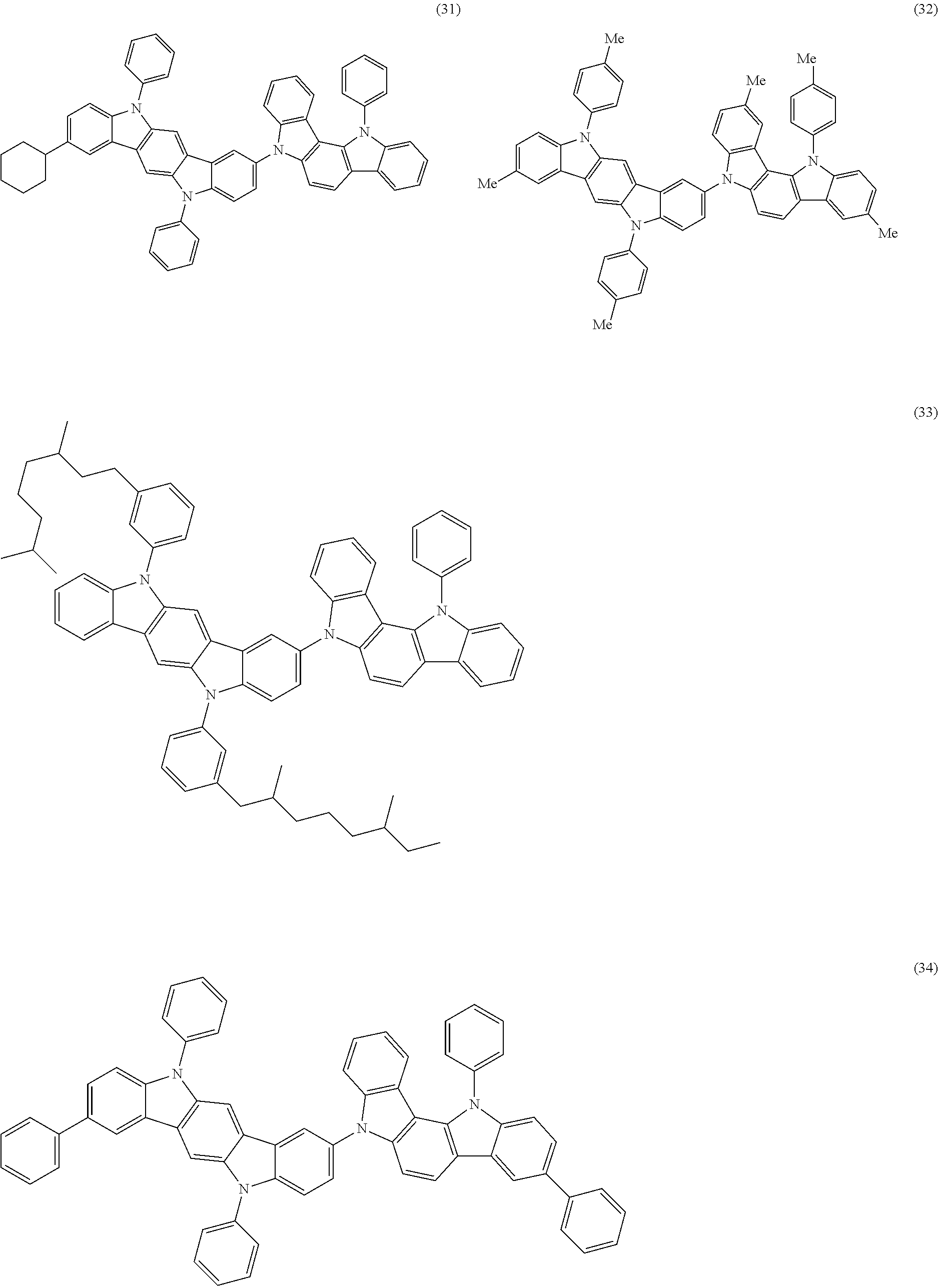 [SMILES: c1ccc(-n2c3ccc(C4CCCCC4)cc3c3cc4c(cc32)c2cc(-n3c5ccccc5c5c3ccc3c6ccccc6n(-c6ccccc6)c35)ccc2n4-c2ccccc2)cc1 ; Cc1ccc(-n2c3ccc(C)cc3c3cc4c(cc32)c2cc(-n3c5ccc(C)cc5c5c3ccc3c6cc(C)ccc6n(-c6ccc(C)cc6)c35)ccc2n4-c2ccc(C)cc2)cc1 ; CCC(C)CCCC(C)Cc1cccc(-n2c3ccc(-n4c5ccccc5c5c4ccc4c6ccccc6n(-c6ccccc6)c45)cc3c3cc4c(cc32)c2ccccc2n4-c2cccc(CCC(C)CCCC(C)C)c2)c1 ; c1ccc(-c2ccc3c(c2)c2cc4c(cc2n3-c2ccccc2)c2cc(-n3c5ccccc5c5c3ccc3c6cc(-c7ccccc7)ccc6n(-c6ccccc6)c35)ccc2n4-c2ccccc2)cc1]

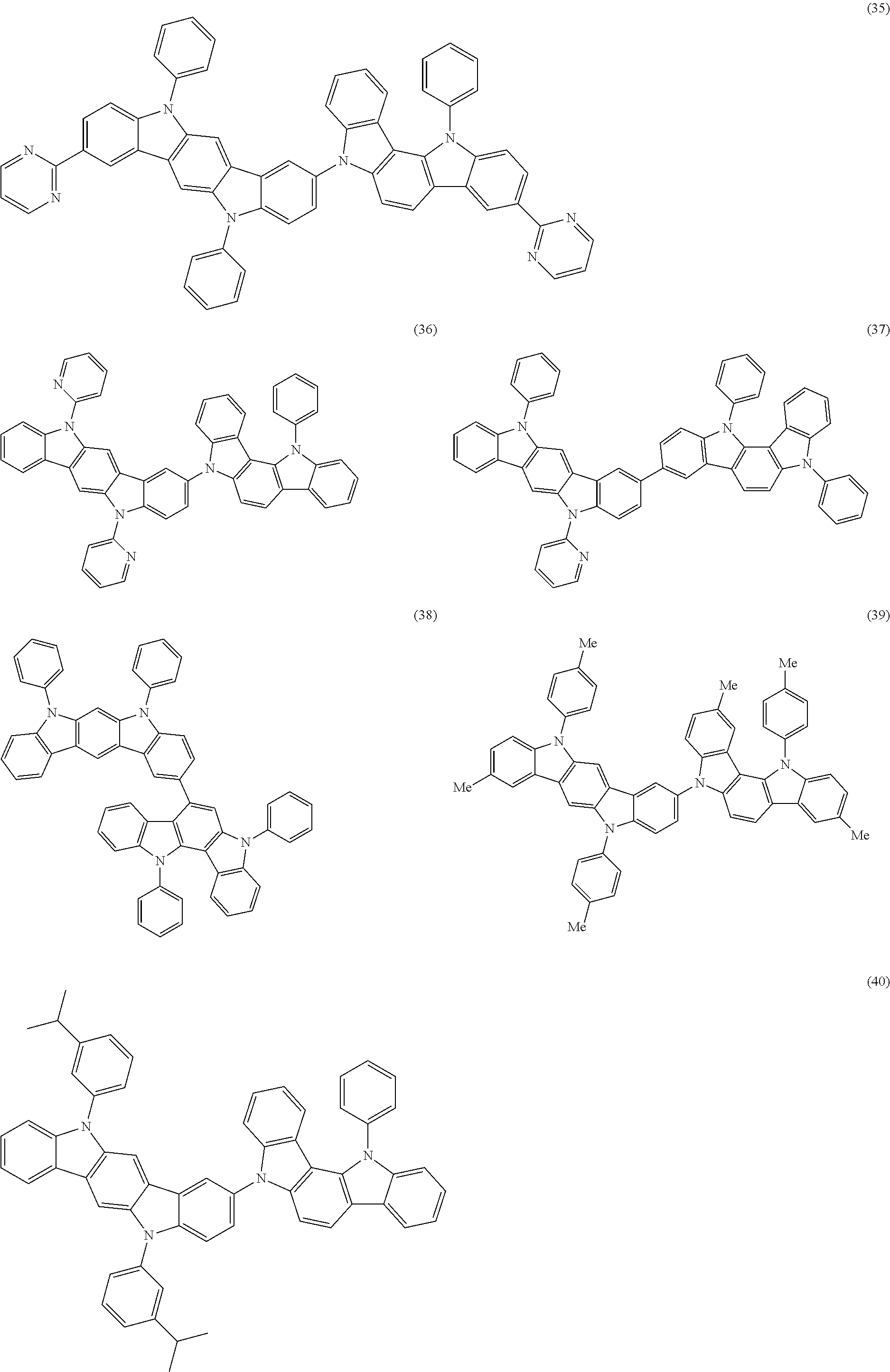

The indolocarbazole derivative according to an embodiment may have the above-described chemical structure, and an emission layer having high efficiency and long life may be formed in an organic EL device. In the indolocarbazole derivative according to an embodiment, the indolocarbazolyl group positioned at A and the indolocarbazolyl group positioned at B may have an asymmetric structure with respect to the connecting part L, and amorphous properties and the thermal stability of the emission layer may be improved when using the indolocarbazole derivative as the host material of the emission layer. In addition, the indolocarbazole derivative according to an embodiment may be used as a material for forming a hole transport layer.

Organic EL Device

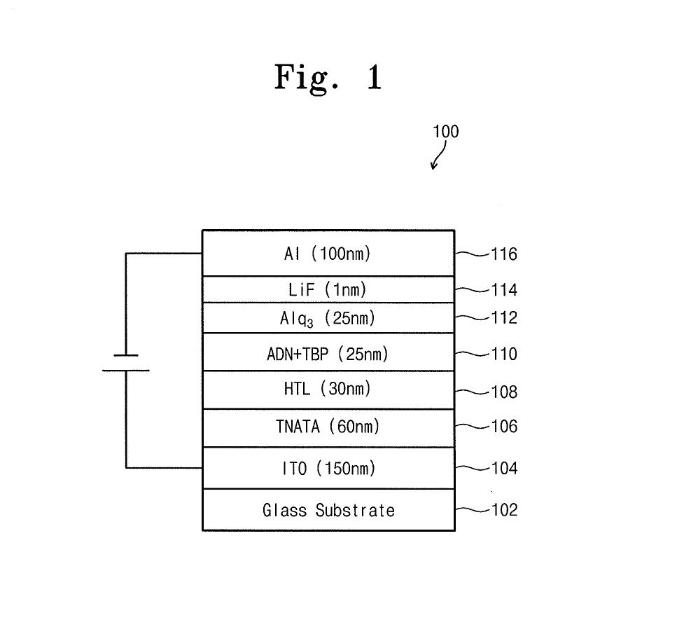

An organic EL device manufactured by using an indolocarbazole derivative according to an embodiment will be explained. FIG. 1 illustrates a schematic diagram of an organic EL device 100 according to an embodiment. The organic EL device 100 may include, e.g., a substrate 102, a positive electrode 104, a hole injection layer 106, a hole transport layer 108, an emission layer 110, an electron transport layer 112, an electron injection layer 114, and a negative electrode 116.

The substrate 102 may be, e.g., a transparent glass substrate, a flexible substrate of a semiconductor substrate resin including silicon, or the like. The following thin layers may be formed by a layer forming method in vacuum or by various coating methods. The positive electrode 104 may be disposed on the substrate 102 and may be formed by using indium tin oxide (ITO), indium zinc oxide (IZO), or the like. The hole injection layer 106 may be disposed on the positive electrode 104 and may include 4,4′,4″-tris(N-1-naphthyl-N-phenylamino)triphenylamine (1-TNATA), 4,4-bis-(N,N-di(3-tolyl)amino)-3,3-dimethylbiphenyl (HMTPD), or the like. The hole transport layer 108 may be disposed on the hole injection layer 106 and may be formed by using α-NPD (N,N′-di-[(1-naphthyl)-N,N′-diphenyl-1,1′-biphenyl]-4,4′-diamine; NPB), N,N′-bis(3-methylphenyl)-N,N′-diphenylbenzidine (TPD), 4,4′-cyclohexylidenebis[N,N-bis(4-methylphenyl)benzeneamine] (TACP), a triphenylamine tetramer, HMTPD, or the like. The emission layer 110 may be disposed on the hole transport layer 108 and may be formed by doping N,N,N′,N′-tetraphenylbenzidine (TPB) or tris(2-phenylpyridinato)iridium(III) (Ir(ppy)₃) into the host material according to an embodiment. The electron transport layer 112 may be disposed on the emission layer 110 and may be formed by using a material including, e.g., tris(8-hydroxyquinolinato)aluminum (Alq₃). The electron injection layer 114 may be disposed on the electron transport layer 112 and may be formed by using a material including, e.g., lithium fluoride (LiF). The negative electrode 116 may be formed on the electron injection layer 114 and may be formed by using a metal such as Al or a transparent material such as ITO, IZO, or the like. In addition, the thin layers may be formed by an appropriate layer forming method according to the material used, e.g., a vacuum deposition method, a sputtering method, various coasting methods, or the like.

By using the indolocarbazole derivative according to an embodiment as the host material in the organic EL device 100, an emission layer having high efficiency and long life may be formed. In addition, the indolocarbazole derivative according to an embodiment may be applied in an organic EL apparatus of an active matrix using a thin film transistor (TFT).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

Synthesis

The indolocarbazole derivative was synthesized according to the following Reaction Scheme 1.

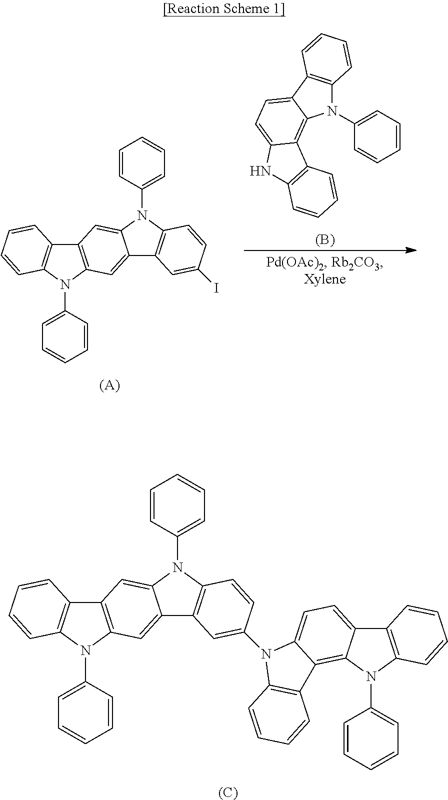

Synthesis of Compound C

5.00 g (8.94 mmol) of iodine-type Compound A, 3.12 g (9.39 mmol) of indolocarbazole (Compound B), 60.2 mg (0.268 mmol) of palladium acetate, and 6.19 g (2.68 mmol) of rubidium carbonate were added into 300 ml of xylene. Under a nitrogen gas atmosphere, 0.358 ml (1.5 M in xylene, 0.536 mmol) was added and refluxed while stirring for 48 hours. The reactant was cooled, and water was added. Extraction was performed using chloroform, and an organic layer was washed using water and a saturated saline solution in order and dried using anhydrous magnesium sulfate. The organic layer thus obtained was filtered, concentrated, and purified by means of a flash chromatography (cyclohexane/toluene=5/1→1/1) to produce 2.51 g of Compound C (3.40 mmol, yield 38%).

The synthesized compounds were identified by measuring mass spectrum.

Through performing the above-described preparation method, the compound of Example 1 was obtained. In addition, the compound of Comparative Example 1 was obtained. The compounds of Example 1 and Comparative Example 1 are shown below.

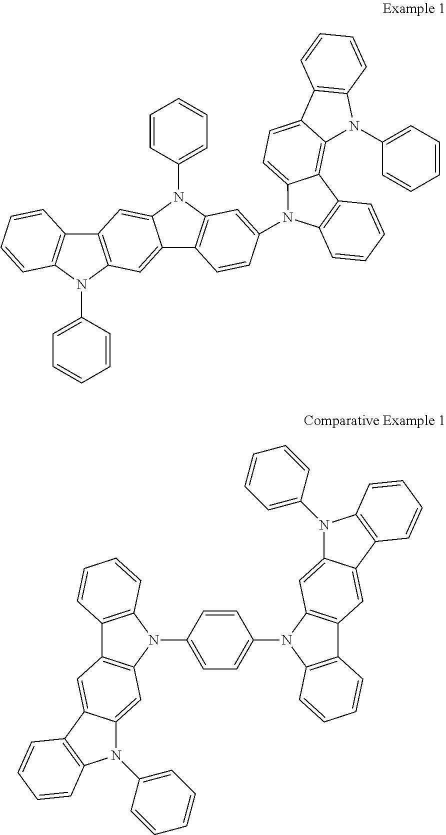 [SMILES: c1ccc(-n2c3ccccc3c3cc4c(cc32)c2ccc(-n3c5ccccc5c5c3ccc3c6ccccc6n(-c6ccccc6)c35)cc2n4-c2ccccc2)cc1 ; c1ccc(-n2c3ccccc3c3cc4c5ccccc5n(-c5ccc(-n6c7ccccc7c7cc8c9ccccc9n(-c9ccccc9)c8cc76)cc5)c4cc32)cc1]

By using the compounds of Example 1 and Comparative Example 1 as host materials, the above-described organic EL devices were manufactured. The substrate 102 was formed by using a transparent glass substrate, the positive electrode 104 was formed by using ITO into a thickness of about 150 nm, and the hole injection layer 106 was formed by using 1-TNATA into a thickness of about 60 nm. The hole transport layer 108 was formed by using HMTPD into a thickness of about 30 nm, the emission layer 110 (obtained by doping Ir(ppy)₃ by 20% into the host materials of Example 1 and Comparative Example 1) was formed into a thickness of about 25 nm, the electron transport layer 112 was formed by using Alq₃ into a thickness of about 25 nm, the electron injection layer 114 was formed by using LiF into a thickness of about 1 nm, and the negative electrode 116 was formed by using Al into a thickness of about 100 nm.

With respect to the manufactured organic EL devices, a voltage, light-emitting efficiency, and half-life were evaluated. The light-emitting efficiency was measured at about 10 mA/cm², and the half-life was measured based on an initial luminance of about 1,000 cd/m². The evaluation results are illustrated in the following Table 1.

TABLE 1

| | | Light-emitting efficiency | |
|---|---|---|---|
| | Voltage (V) | (cd/A) | Half-life (hr) |
| Example 1 | 4.2 | 32.1 | 2,900 |
| Comparative | 4.9 | 29.4 | 1,050 |
| Example 1 | | | |

Referring to Table 1, the organic EL device including the compound of Example 1 was driven by a lower voltage than the organic EL device including the compound of Comparative Example 1. In addition, the light-emitting efficiency for the device using the compound of Example 1 was higher than that using the compound of Comparative Example 1. With respect to the half-life, the compound of Example 1 exhibited quite a longer half-life when compared to the compound of Comparative Example 1. Without being bound by theory, it is believed that the results may be obtainable because the compound of Example 1 had a structure including two asymmetric indolocarbazolyl groups with a connecting part therebetween, and improved layer stability may be obtained when forming a layer. In addition, the functions of the indolocarbazole derivatives may be separated, and the deterioration of the light-emitting life may be considered to be restrained when compared to an indolocarbazole derivative having a symmetric structure.

By way of summation and review, when using the organic EL device for a display apparatus, the organic EL device may have high efficiency and long life. In order to realize the high efficiency and long life, a host material constituting an emission layer has been considered.

The embodiments may provide a host material for manufacturing an organic EL device having high efficiency and long life.

The embodiments may provide an organic EL device having high efficiency and long life, and a host material for an organic EL device having high efficiency and long life, including an indolocarbazole derivative.

The embodiments may provide an indolocarbazole derivative having improved amorphous properties.

The indolocarbazole derivative according to an embodiment may form an emission layer having high efficiency and long life in an organic EL device.

The indolocarbazole derivative according to an embodiment of the inventive concept may have an asymmetric structure of two indolocarbazolyl groups with the connecting part therebetween, amorphous properties may be improved, and the thermal stability of an emission layer may be improved.

In the indolocarbazole derivative according to an embodiment, an asymmetric structure with respect to the connecting part may be obtained, and as a result, amorphous properties may be improved, and the thermal stability of an emission layer may be improved when forming the emission layer.

In the indolocarbazole derivative according to an embodiment, the connecting part L may be the single bond, and a distance between two indolocarbazolyl groups may be decreased. In this case, an angle between two faces formed by the two indolocarbazolyl groups may be increased, planarity may be lowered, and a stacking effect between indolocarbazole derivatives may be restrained.

In the indolocarbazole derivative according to an embodiment, at least one end of the single bond of the connecting part L may be directly connected to the benzene ring included in the indolocarbazole skeleton of one of the indolocarbazole groups, and the distance between two indolocarbazolyl groups may be decreased. In this case, an angle between two faces formed by the two indolocarbazolyl groups may be increased, and the planarity may be lowered, and stacking effect between indolocarbazole derivatives may be restrained.

In the indolocarbazole derivative according to an embodiment, both ends of the single bond of the connecting part L may be directly connected to the benzene rings included in the indolocarbazole skeletons of the inodolocarbazole groups, and the distance between two indolocarbazolyl groups may be decreased. In this case, an angle between two faces formed by the two indolocarbazolyl groups may be increased, and the planarity may be lowered, and stacking effect between indolocarbazole derivatives may be restrained.

The organic EL device according to an embodiment may be manufactured by using an emission layer having high efficiency and long life.

In the organic EL device according to an embodiment, stacking effect between the indolocarbazole derivatives may be restrained, and amorphous properties may be improved. When the indolocarbazole derivative is used as the host material of the emission layer, the layer stability of the emission layer may be improved.

According to an embodiment, an organic EL device having high efficiency and long life, and a host material including an indolocarbazole derivative for an organic EL device realizing the high efficiency and the long life may be provided. In addition, an indolocarbazole derivative improving amorphous properties, layer stability, and carrier transport properties may be provided.

The embodiments may provide a host material for an organic electroluminescence device having high efficiency and long life.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An indolocarbazole derivative having a structure represented by A-L-B, wherein A and B are each independently an indolocarbazolyl group represented by one of Formulae (1) to (6), below: 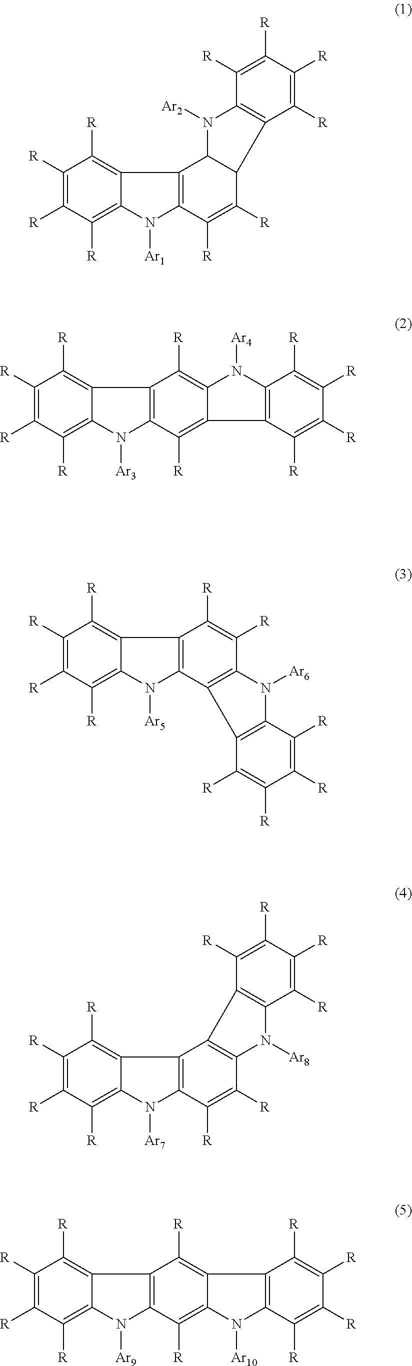 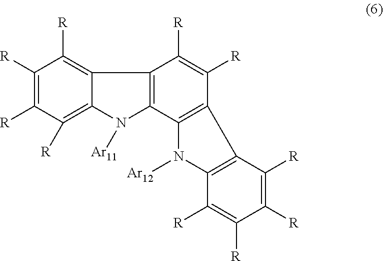
wherein, L is a connecting part and is selected from a single bond, an arylene group, or a heteroarylene group,
Ar₁ to Ar₁₂ are each independnetly a substituted or unsubstituted aryl or heteroaryl group, and
each R is independently hydrogen, an alkyl group, an aryl group, a heteroaryl group having less than or equal to 20 carbon atoms, or the connecting part L.

2. The indolocarbazole derivative as claimed in claim 1, wherein:
the indolocarbazole group A is represented by one of Formulae (1) to (6) and the indolocarbazole group B is represented by a different one of Formulae (1) to (6), and
the indolocarbazole derivative has an asymmetric structure.

3. The indolocarbazole derivative as claimed in claim 1, wherein, when the indolocarbazolyl group A and the indolocarbazolyl group B are each independently represented by one of Formulae (1) to (6):
a kind of An to Ar₁₂ of the indolocarbazole group A is different from a kind of Ar₁ to Ar₁₂ of the indolocarbazole group B,
a number and/or a kind of R of the indolocarbazole group A is different from a number and/or a kind of R of the indolocarbazole group B, or
a binding site of the connecting part L to the indolocarbazole group A is different from a binding site of the connecting part L to the indolocarbazole group B.

4. The indolocarbazole derivative as claimed in claim 3, wherein the connecting part L is the single bond.

5. The indolocarbazole derivative as claimed in claim 4, wherein at least one end of the single bond is bound to a benzene ring included in an indolocarbazole skeleton of the indolocarbazolyl group A or the indolocarbazolyl group B.

6. The indolocarbazole derivative as claimed in claim 5, wherein both ends of the single bond are bound to benzene rings respectively included in the indolocarbazole skeletons of the indolocarbazolyl group A and the indolocarbazolyl group B.

7. The indolocarbazole derivative as claimed in claim 1, wherein the connecting part L is the single bond.

8. An organic electroluminescence device comprising an emission layer, the emission layer including an indolocarbazole derivative having a structure represented by A-L-B, wherein A and B are each independently an indolocarbazolyl group represented by one of Formulae (1) to (6), below: 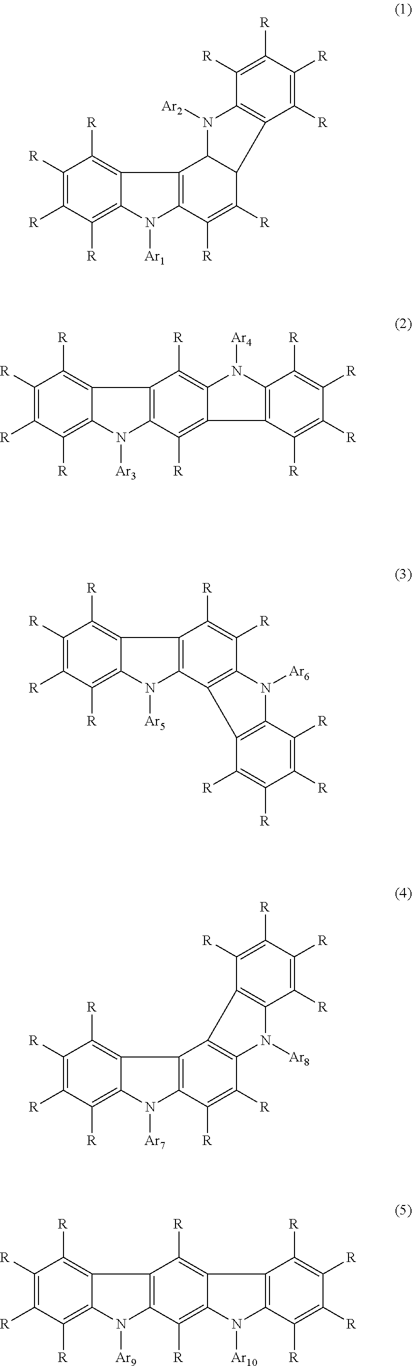 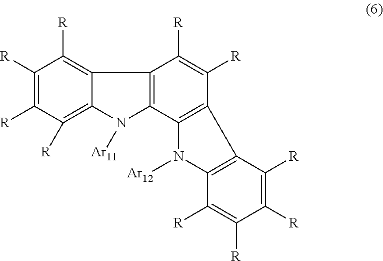
wherein, L is a connecting part and is selected from a single bond, an arylene group, or a heteroarylene group,
Ar₁ to Ar₁₂ are each independnetly a substituted or unsubstituted aryl or heteroaryl group, and
each R is independently hydrogen, an alkyl group, an aryl group, a heteroaryl group having less than or equal to 20 carbon atoms, or the connecting part L.

9. The organic electroluminescence device as claimed in claim 8, wherein:
the indolocarbazole group A is represented by one of Formulae (1) to (6) and the indolocarbazole group B is represented by a different one of Formulae (1) to (6), and
the indolocarbazole derivative has an asymmetric structure.

10. The organic electroluminescence device as claimed in claim 8, wherein, when the indolocarbazolyl group A and the indolocarbazolyl group B are each independently represented by one of Formulae (1) to (6):
a kind of Ar₁ to Ar₁₂ of the indolocarbazole group A is different from a kind of Ar₁ to Ar₁₂ of the indolocarbazole group B,
a number and/or a kind of R of the indolocarbazole group A is different from a number and/or a kind of R of the indolocarbazole group B, or
a binding site of the connecting part L to the indolocarbazole group A is different from a binding site of the connecting part L to the indolocarbazole group B.

11. Then organic electroluminescence device as claimed in claim 10, wherein the connecting part L is the single bond.

12. The organic electroluminescence device as claimed in claim 11, wherein at least one end of the single bond is bound to a benzene ring included in an indolocarbazole skeleton of the indolocarbazolyl group A or the indolocarbazolyl group B.

13. The organic electroluminescence device as claimed in claim 12, wherein both ends of the single bond are bound to benzene rings respectively included in the indolocarbazole skeletons of the indolocarbazolyl group A and the indolocarbazolyl group B.

14. The organic electroluminescence device as claimed in claim 8, wherein the connecting part L is the single bond.
